(19) United States
(12) Patent Application Publication
(10) Pub. No.: US 2009/0151780 A1
(43) Pub. Date: Jun. 18, 2009

(54) Litroenergy power cell

(76) Inventor: Michael P. Kohnen, II, Turtle Lake, WI (US)

Correspondence Address: Tipton L. Randall, 19371 55th Avenue, Chippewa Falls, WI, 54729, US

(21) Appl. No.: 12/316,853

(22) Filed: Dec. 17, 2008

Related U.S. Application Data
(60) Provisional application No. 61/007,970, filed on Dec. 18, 2007.

(51) Int. Cl. H01L 31/00

(52) U.S. Cl. 136/252

(57) ABSTRACT

A litroenergy power cell assembly includes a photovoltaic cell sheet member for producing electrical energy from light energy impinging there upon. A litrocell sheet member is positioned adjacent the photovoltaic cell sheet member. The litrocell sheet member includes a light-transparent matrix having dispersed therein a plurality of light-emitting phosphor particles in association with a tritium containing substance. The tritium containing substance excites the phosphor particles. Light emitted by the phosphor particles traverses the light-transparent matrix of the litrocell sheet member, and impinges upon the photovoltaic cell sheet member to produce electrical energy therefrom.

### CROSS-REFERENCE TO RELATED APPLICATIONS, IF ANY

This application claims the benefit under 35 U.S.C. §119 (e) of co-pending provisional application Ser. No. 61/007,970, filed Dec. 18, 2007. Application Ser. No. 61/007,970 is hereby incorporated by reference.

### STATEMENT REGARDING FEDERALLY SPONSORED RESEARCH OR DEVELOPMENT

Not applicable.

### REFERENCE TO A MICROFICHE APPENDIX, IF ANY

Not applicable.

### BACKGROUND OF THE INVENTION

1. Field of the Invention

The present invention relates to power cells and, more particularly, to power cells that produce electrical energy for various applications and, most particularly, to power cells that produce electrical energy for extended periods with minimal maintenance, and with no need for replenishment of components during the extended period of operation.

2. Background Information

Power cells are well-known devices that generate electrical energy from an enclosed system to power a connected device that achieves a desired result. The simplest power cell is a battery that derives electrical energy from a chemical reaction within the battery. For example, a flash light includes one or more dry cell batteries connected to a light bulb, with the system enclosed in a case for easy use and transport. Such dry cell batteries eventually use up the chemicals within and cease to function. Recently, rechargable dry cell batteries have become available. Rechargable wet cell batteries are also comedically available and are commonly used in vehicles and other applications where extended service is needed. The chemical reactions that provides electrical energy from such batteries are reversible and application of electrical energy from an outside source drives the reaction in reverse, thereby storing energy within the battery and recharging it.

Another power cell is the catalytic membrane cell, or fuel cell, that derives electrical energy from the reaction of hydrogen and oxygen that produces water. These gaseous elements are separated by a catalytic membrane upon which the oxidation reaction occurs. Such fuel cells are very expensive and find limited use at present.

A more recent technological development is a photovoltaic cell that produce electrical energy directly from light energy that falls upon the photocell. Such photovoltaic cells, in the form of large panels, are mounted to face the sun and produce electrical energy from sunlight. Because of limited efficiency, a large surface area for the cells is needed to produce meaningful amounts of electrical energy. Recently, relatively small surface area photovoltaic cells have been employed to power calculators and similar devices that require limited amounts of electrical energy to operate.

Applicant has devised a power cell that is self-contained and provides the continuous production of electrical energy for extended periods of time, on the order of years, with minimal maintenance and without the need for replenishment of any component of the power cell.

### SUMMARY OF THE INVENTION

The present invention is directed to a litroenergy power cell assembly. The assembly comprises a photovoltaic cell sheet member for producing electrical energy from light energy impinging there upon. A litrocell sheet member is positioned adjacent the photovoltaic cell sheet member. The litrocell sheet member includes a light-transparent matrix having dispersed therein a plurality of light-emitting phosphor particles in association with a tritium containing substance. The tritium containing substance excites the phosphor particles. Light emitted by the phosphor particle traverses the light-transparent matrix of the litrocell sheet member, and impinge upon the photovoltaic cell sheet member to produce electrical energy there from.

In a preferred embodiment of the invention, the litroenergy power cell assembly includes a plurality of photovoltaic cell sheet members aligned in register and having a selected separation between adjacent sheet members. The photovoltaic cell sheet members produce electrical energy from light energy impinging there upon. A plurality of litrocell sheet members are present, with each litrocell sheet member positioned between adjacent the photovoltaic cell sheet members. Each litrocell sheet member includes a light-transparent matrix having dispersed therein a plurality of light-emitting phosphor particles in association with a tritium containing substance. The tritium containing substance excites the phosphor particles. Light emitted by the phosphor particles traverses the light-transparent matrix of the litrocell sheet member, and impinges upon an adjacent photovoltaic cell sheet member to produce electrical energy therefrom.

In a further embodiment of the present invention, the litroenergy power cell assembly includes a plurality of photovoltaic cell sheet members aligned in register and having a selected separation between adjacent sheet members. The photovoltaic cell sheet members produce electrical energy from light energy impinging there upon. A plurality of litrocell sheet members are present, with each litrocell sheet member positioned between adjacent the photovoltaic cell sheet members. Each litrocell sheet member includes a light-transparent matrix having dispersed therein a plurality of light-emitting phosphor particles in association with a tritium containing substance. The tritium containing substance excites the phosphor particles. A charging control unit is in electrical connection with the plurality of photovoltaic cell sheet members. The charging control unit provides controlled output of the litroenergy power cell assembly. A battery unit receives electrical current from the charge control member, with the battery unit providing direct current power therefrom. An inverter unit receives direct current power from the battery unit, with the inverter unit providing alternating current power therefrom. Light emitted by the phosphor particles traverses the light-transparent matrix of the litrocell sheet member, and impinges upon an adjacent photovoltaic cell sheet member to produce electrical energy therefrom.

### BRIEF DESCRIPTION OF THE DRAWINGS

FIG. 1 is a cross sectional view of a light-transparent microsphere of the present invention containing light-emitting phosphor particles and a radioactive gas.

FIG. 2 is a cross sectional view of a first embodiment of the litroenergy power cell of the present invention.

FIG. 3 is a perspective view of the first embodiment of the litroenergy power cell of FIG. 1 of the present invention.

FIG. 4 is a schematic representation of a second embodiment of the litroenergy power cell assembly of the present invention.

FIG. 5 is a detailed schematic representation of the second embodiment of the litroenergy power cell assembly of the present invention.

### DESCRIPTION OF THE EMBODIMENTS

### Nomenclature

10 Litroenergy Power Cell Assembly

20 Photovoltaic Cell Sheet Member

22 Electrical Conductors

30 Litrocell Sheet Member

32 Light-Transparent Matrix

34 Light-Transparent Microspheres

36 Phosphor Particles

38 Tritium Gas

39 Beta Radiation

40 Charge Controlling Unit

42 Electrical Conductors

50 Battery Unit

52 Electrical Conductors

54 DC Socket Member

60 Inverter Unit

64 AC Socket Member

70 Assembly Housing Member

### Construction

The invention is a litroenergy power cell assembly. The assembly comprises a photovoltaic cell sheet member for producing electrical energy from light energy impinging there upon. A litrocell sheet member is positioned adjacent the photovoltaic cell sheet member. The litrocell sheet member includes a light-transparent matrix having dispersed therein a plurality of light-emitting phosphor particles in association with a tritium containing substance. The tritium containing substance excites the phosphor particles. Light emitted by the phosphor particles traverses the light-transparent matrix of the litrocell sheet member, and impinges upon the photovoltaic cell sheet member to produce electrical energy there from.

In a preferred embodiment of the invention, the litroenergy power cell assembly includes a plurality of photovoltaic cell sheet members aligned in register and having a selected separation between adjacent sheet members. The photovoltaic cell sheet members produce electrical energy from light energy impinging there upon. A plurality of litrocell sheet members are present, with each litrocell sheet member positioned between adjacent the photovoltaic cell sheet members. Each litrocell sheet member includes a light-transparent matrix having dispersed therein a plurality of light-emitting phosphor particles in association with a tritium containing substance. The tritium containing substance excites the phosphor particles. Light emitted by the phosphor particles traverses the light-transparent matrix of the litrocell sheet member, and impinges upon an adjacent photovoltaic cell sheet member to produce electrical energy therefrom.

In a further embodiment of the present invention, the litroenergy power cell assembly includes a plurality of photovoltaic cell sheet members aligned in register and having a selected separation between adjacent sheet members. The photovoltaic cell sheet members produce electrical energy from light energy impinging there upon. A plurality of litrocell sheet members are present, with each litrocell sheet member positioned between adjacent the photovoltaic cell sheet members. Each litrocell sheet member includes a light-transparent matrix having dispersed therein a plurality of light-emitting phosphor particles in association with a tritium containing substance. The tritium containing substance excites the phosphor particles. A charging control unit is in electrical connection with the plurality of photovoltaic cell sheet members. The charging control unit provides controlled output of the litroenergy power cell assembly. A battery unit receives electrical current from the charge control member, with the battery unit providing direct current power therefrom. An inverter unit receives direct current power from the battery unit, with the inverter unit providing alternating current power therefrom. Light emitted by the phosphor particles traverses the light-transparent matrix of the litrocell sheet member, and impinges upon an adjacent photovoltaic cell sheet member to produce electrical energy therefrom.

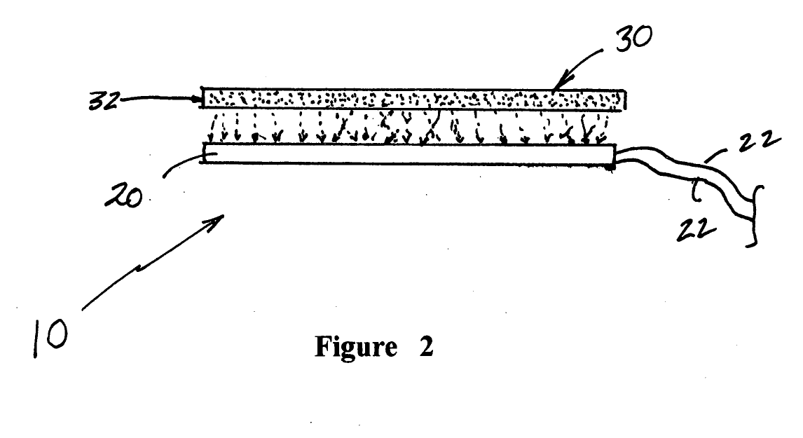

Referring first to FIG. 2, a first embodiment of the litroenergy power cell assembly 10 is illustrated. The power cell assembly 10 comprises a photovoltaic cell sheet member 20 for producing electrical energy from light energy impinging there upon. The photovoltaic cell sheet member 20 is well-known in the industry and available from numerous commercial sources. A photovoltaic cell sheet member 20 is made up of two layers of semiconducting material, termed P and N. The boundary between P and N layers acts as a diode. That is, electrons can move from N to P but not the opposite way. Light with sufficient energy impinging on the diode layers cause electrons to move from the P layer into the N layer. An excess of electrons build up in the N layer, while the P layer builds up a shortage. This results in a voltage difference between the N and P layers that can be used as a power source. As long as the photovoltaic cell 20 receives sufficient light, the voltage difference between the diode layers is maintained. An electrical conductor 22 is connected to each layer of the photovoltaic cell 20 to transfer the electrical energy produced by the cell. The photovoltaic cell sheet member 20 may be relatively rigid or it may be somewhat flexible, depending upon the method of manufacture. A pair of electrical conductors 22 are connected to the photovoltaic cell sheet member 20 for conducting electrical current produced by the sheet member 20, as described above.

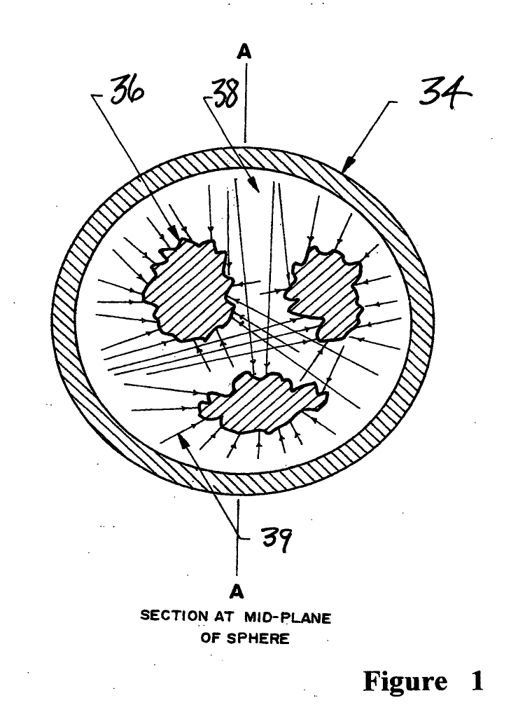

A litrocell sheet member 30 is positioned adjacent the photovoltaic cell sheet member 20. The litrocell sheet member 30 includes a light-transparent matrix 32 with a plurality of light-transparent microspheres 34 dispersed there through. Preferably the light-transparent matrix 32 is selected from glass, ceramic or polymeric resin material, while the light-transparent microspheres 34 are fabricated from glass or polymeric resin material. The microspheres 34 contain light-emitting phosphor particles 36 and a radioactive gas 38 therein that excites the phosphor particles 36, as shown in FIG. 1. Preferably the radioactive gas 38 is tritium, and the gas 38 is present within the light-transparent microspheres 34 at a pressure greater than atmospheric pressure. The tritium gas 38 emits “soft” beta radiation 39, thereby exciting the phosphor particles 36, which, in turn emits light energy. The details of the production and features of the microspheres 34 are fully disclosed in applicant's co-pending utility patent application Ser. No. 11/710,345 filed Feb. 23, 2007, and published as US 2007/0200074 on Aug. 30, 2007. The contents of this application are hereby incorporated by reference.

Nearly any phosphor particles 36 that emit visible light are suitable for inclusion within the microspheres 34. One type of phosphor particle 36 that is particularly useful for the present invention has the general formula: MO(n-x){aAl₂O₃^{α}+(1-a)Al₂O₃^{γ}}xB₂O₃: R, where M is any alkaline earth metal preferably selected from among Sr, Ca and Ba, and R is a rare earth element selected from La, Ce, Pr, Nd, Sm, Gd, Tb, Dy, Ho, Er, Tm, Yb, Lu, Mn and Bi. Most preferably, the phosphor particles 36 of the present invention contain strontium aluminate borate.

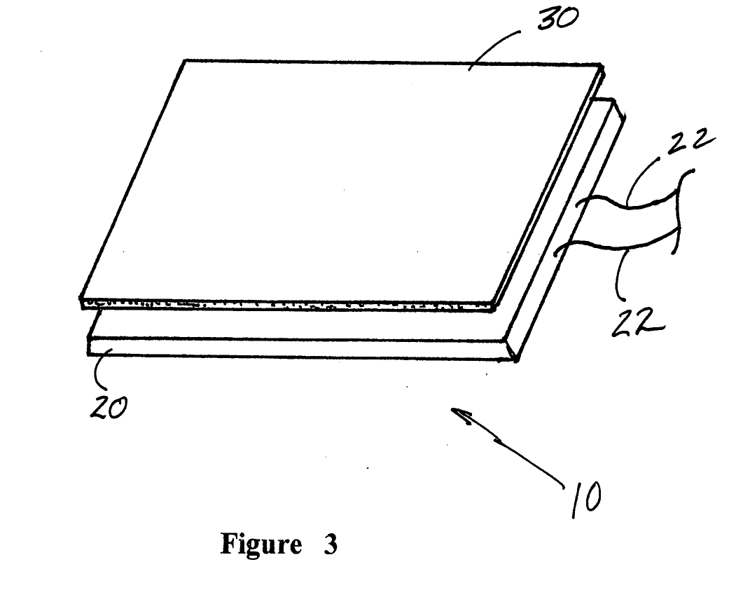

Light emitted by the phosphor particles 36 traverses the microsphere 34, the light-transparent matrix 32 of the litrocell sheet member 30, and impinges upon the photovoltaic cell sheet member 20 to produce electrical -energy therefrom, as illustrated in FIG. 2. The light-transmitting matrix 32 can be relatively thin, for example, a thin film produced by painting a fluid suspension of the microspheres 34 on the surface of the photovoltaic sheet member 20 and allowing the suspension to dry. Preferably, the photovoltaic sheet member 20 and the litrocell sheet member 30 are of equal dimensions and the two sheet members 20, 30 are positioned in register, as shown in FIG. 3. When tritium gas 38 is employed as the radioactive gas within the light-transparent microspheres 34, light energy is produced for extended periods by the litrocell sheet member 30. Tritium gas has a half-life of 12.5 years, resulting in at least about 25 years of useful light production for the light-transparent microspheres 34.

In an alternative embodiment of the invention, the light-transparent matrix 32 of the litrocell sheet member 30 includes a tritium containing substance selected from the group consisting of a liquid tritium compound, such as tritium water, T₂O, and a solid tritium compound, such as a tritiated polymeric resin. The tritium compound and phosphor particles 36 are dispersed within the light-transparent matrix 32. The tritium containing substance excites the phosphor particles 36, which, in turn emits light energy that impinges upon the photovoltaic cell 20 to produce electrical energy. Again, the light-transmitting matrix 32 can be relatively thin, for example, a thin film produced by painting a fluid suspension of the tritium compound and phosphor particles 36 on the surface of the photovoltaic sheet member 20 and allowing the suspension to dry.

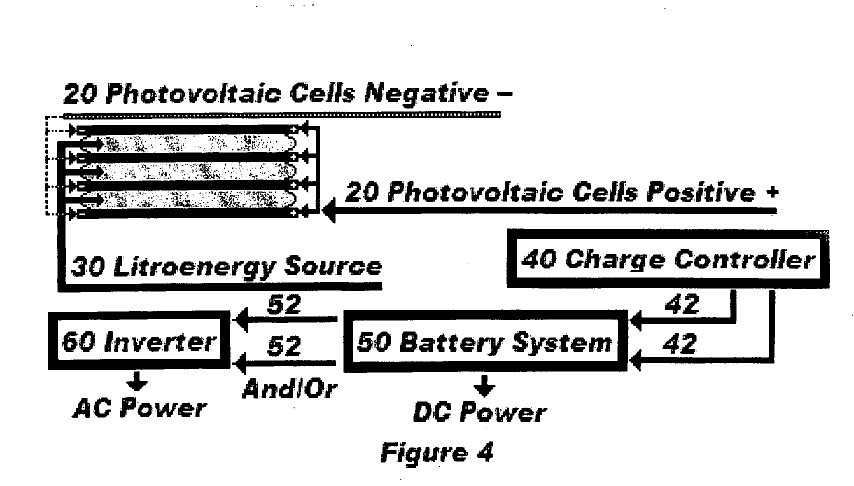

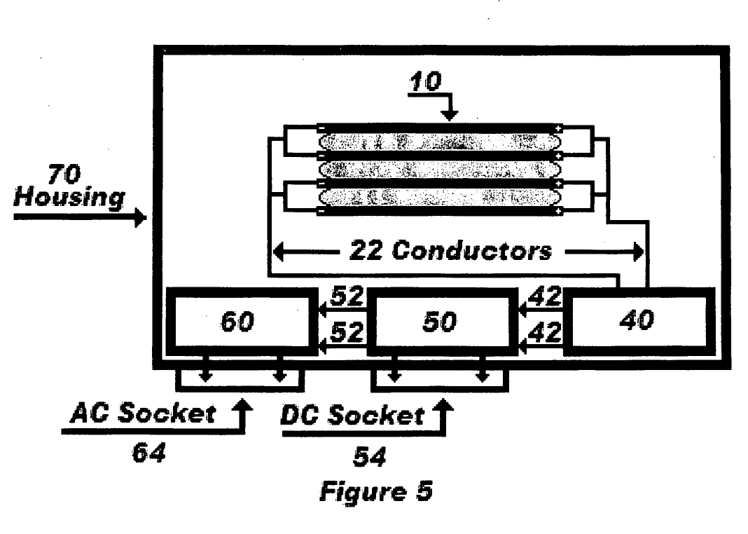

Although extensive banks of individual photovoltaic cell sheet members 20 associated with individual litrocell sheet members 30 might be envisioned, it is more advantageous to employ an alternating stacked arrangement of the sheet members 20, 30, as shown in FIGS. 4 and 5. In this second embodiment of the invention, the litroenergy power cell assembly 10 includes a plurality of photovoltaic cell sheet members 20 aligned in register and having a selected separation between adjacent sheet members 20. The photovoltaic cell sheet members 20 produce electrical energy from light energy impinging there upon. A plurality of litrocell sheet members 30 are present, with each litrocell sheet member 30 positioned between adjacent the photovoltaic cell sheet members 20. Each litrocell sheet member 30 includes a light-transparent matrix 32 with a plurality of light-transparent microspheres 34 dispersed there through. The microspheres 34 contain light-emitting phosphor particles 36 and radioactive tritium gas 38 therein that excites the phosphor particles 36, as described in detail above. Light emitted by the phosphor particles 36 traverses the microsphere 34, the light-transparent matrix 32 of the litrocell sheet member 30, and impinges upon an adjacent photovoltaic cell sheet member 20 to produce electrical energy therefrom. Alternatively, the light-transparent matrix 32 of the litrocell sheet member 30 includes a tritium containing substance selected from the group consisting of a liquid tritium compound, such as tritium water, T₂O, and a solid tritium compound, such as a tritiated polymeric resin. The tritium compound and phosphor particles 36 are dispersed within the light-transparent matrix 32 and produce light, as described above.

Electrical conductors 22 from each photovoltaic cell sheet member 20 are joined and connected to a charge controlling unit 40 that regulates the electrical current and voltage generated by the stacked sheet members 20, 30. The photovoltaic cell sheet members 20 may be connected in series, in parallel, or a combination thereof to achieve the desired voltage and current for a particular application. For example, the photovoltaic cell sheet members 20 of FIG. 5 are connected in parallel, which provides a total output voltage equal to the voltage of one photovoltaic cell sheet member 20, and a current equal to the sum of all photovoltaic cell sheet members 20 combined.

A battery unit 50 receives electrical current from the charge controlling unit 40 via electrical conductors 42 and provides direct current from a DC socket member 54. The battery unit 50 also provides electrical current to an inverter unit 60 via electrical conductors 52. The inverter unit 60 converts the direct current from the battery unit 50 to alternating current and provides alternating current from an AC socket member 64. All of the elements of the litroenergy power cell assembly 10 and associated electrical power handling units 40, 50, 60 are contained within an assembly housing member 70, which provides a compact system for generating electrical power as both direct current (DC) and alternating current (AC).

While the invention has been particularly shown and described with reference to preferred embodiments thereof, it will be understood by those skilled in the art that various changes in form and details may be made therein without departing from the spirit and scope of the invention.

I claim:

1. A litroenergy power cell assembly comprising:
a photovoltaic cell sheet member for producing electrical energy from light energy impinging there upon; and
a litrocell sheet member positioned adjacent the photovoltaic cell sheet member, the litrocell sheet member including a light-transparent matrix having dispersed therein a plurality of light-emitting phosphor particles in association with a tritium containing substance, the tritium containing substance exciting the phosphor particles;
whereby light emitted by the phosphor particles traverses the light-transparent matrix of the litrocell sheet member, and impinges upon the photovoltaic cell sheet member to produce electrical energy therefrom.

2. The litroenergy power cell assembly of claim 1, wherein the tritium containing substance includes tritium gas contained within light-transparent microspheres containing phosphor particles the microspheres dispersed within the light-transparent matrix.

3. The litroenergy power cell assembly of claim 2, wherein the tritium gas confined within the microsphere is at a pressure greater than atmospheric pressure.

4. The litroenergy power cell assembly of claim 2, wherein the light-transparent microsphere is selected from the group consisting of glass and polymeric resin.

5. The litroenergy power cell assembly of claim 1, wherein the tritium containing substance is selected from the group consisting of a liquid tritium compound and a solid tritium compound, the tritium compound and phosphor particles dispersed within the light-transparent matrix.

6. The litroenergy power cell assembly of claim 1, wherein the light-transparent matrix of the litrocell sheet member is selected from the group consisting of glass, ceramic and polymeric resin.

7. The litroenergy power cell assembly of claim 1, wherein the photovoltaic cell sheet member and the litrocell sheet member are of equal dimensions and positioned in register.

8. A litroenergy power cell assembly comprising:
a plurality of photovoltaic cell sheet members aligned in register and having a selected separation between adjacent sheet members, the photovoltaic cell sheet members producing electrical energy from light energy impinging there upon; and
a plurality of litrocell sheet members, each litrocell sheet member positioned between adjacent the photovoltaic cell sheet members, each litrocell sheet member including a light-transparent matrix having dispersed therein a plurality of light-emitting phosphor particles in association with a tritium containing substance, the tritium containing substance exciting the phosphor particles;
whereby light emitted by the phosphor particles traverses the light-transparent matrix of the litrocell sheet member, and impinges upon the photovoltaic cell sheet member to produce electrical energy therefrom.

9. The litroenergy power cell assembly of claim 8, wherein the tritium containing substance includes tritium gas contained within light-transparent microspheres containing phosphor particles the microspheres dispersed within the light-transparent matrix.

10. The litroenergy power cell assembly of claim 9, wherein the tritium gas confined within the microsphere is at a pressure greater than atmospheric pressure.

11. The litroenergy power cell assembly of claim 9, wherein the light-transparent microsphere is selected from the group consisting of glass and polymeric resin.

12. The litroenergy power cell assembly of claim 8, wherein the tritium containing substance is selected from the group consisting of a liquid tritium compound and a solid tritium compound, the tritium compound and phosphor particles dispersed within the light-transparent matrix.

13. The litroenergy power cell assembly of claim 8, wherein the light-transparent matrix of the litrocell sheet member is selected from the group consisting of glass, ceramic and polymeric resin.

14. The litroenergy power cell assembly of claim 8, further including a charging control unit in electrical connection with the plurality of photovoltaic cell sheet members, the charging control unit providing controlled output of the litroenergy power cell assembly.

15. The litroenergy power cell assembly of claim 14, further including a battery unit receiving electrical current from the charging control unit, the battery unit providing direct current power therefrom.

16. The litroenergy power cell assembly of claim 15, further including an inverter unit receiving direct current power from the battery unit, the inverter unit providing alternating current power therefrom.

17. A litroenergy power cell assembly comprising:
a plurality of photovoltaic cell sheet members aligned in register and having a selected separation between adjacent sheet members, the photovoltaic cell sheet members producing electrical energy from light energy impinging there upon;
a plurality of litrocell sheet members, each litrocell sheet member positioned between adjacent the photovoltaic cell sheet members, each litrocell sheet member including a light-transparent matrix having dispersed therein a plurality of light-emitting phosphor particles in association with a tritium containing substance, the tritium containing substance exciting the phosphor particles;
a charging control unit in electrical connection with the plurality of photovoltaic cell sheet members, the charging control unit providing controlled output of the litroenergy power cell assembly;
a battery unit receiving electrical current from the charge control member, the battery unit providing direct current power therefrom; and
an inverter unit receiving direct current power from the battery unit, the inverter unit providing alternating current power therefrom;
whereby light emitted by the phosphor particles traverses the light-transparent matrix of the litrocell sheet member, and impinges upon the photovoltaic cell sheet member to produce electrical energy therefrom.

18. The litroenergy power cell assembly of claim 17, wherein the tritium containing substance includes tritium gas contained within light-transparent glass microspheres containing phosphor particles, the microspheres dispersed within the light-transparent matrix.

19. The litroenergy power cell assembly of claim 17, wherein the tritium containing substance is selected from the group consisting of a liquid tritium compound and a solid tritium compound, the tritium compound and phosphor particles dispersed within the light-transparent matrix.

20. The litroenergy power cell assembly of claim 17, further including a housing unit enclosing the plurality of sheet members, the charge control unit, the battery unit and the inverter unit, with a first electrical socket mounted on the housing unit and in electrical connection with the battery unit for providing direct current therefrom, and a second electrical socket mounted on the housing unit and in electrical connection with the inverter unit for providing alternating current therefrom.
